(19) United States
(12) Patent Application Publication
(10) Pub. No.: US 2013/0076361 A1
(43) Pub. Date: Mar. 28, 2013

(54) RF RECEIVING COIL AND MAGNETIC RESONANCE IMAGING APPARATUS USING THE SAME

(71) Applicants: Takeshi Taniguchi, Tokyo (JP); Tooru Oosawa, Tokyo (JP); Chie Kobayashi, Tokyo (JP)

(72) Inventors: Takeshi Taniguchi, Tokyo (JP); Tooru Oosawa, Tokyo (JP); Chie Kobayashi, Tokyo (JP)

(21) Appl. No.: 13/703,134

(22) PCT Filed: May 26, 2011
(86) PCT No.: PCT/JP2011/062051

§ 371 Date: Dec. 10, 2012

(30) Foreign Application Priority Data
Jun. 16, 2010 (JP) 2010-136892

(51) Int. Cl. G01R 33/34

(52) U.S. Cl. CPC G01R 33/34092
USPC 324/322

(57) ABSTRACT

To order to provide an RF receiving coil having a structure that can be safely mounted on an object and an MRI apparatus including the RF receiving coil, the RF receiving coil includes a main body having one or more flexible closed conductor loops for receiving a nuclear magnetic resonance signal, a flexible outer cover section that covers the closed conductor loop, a preamplifier section that amplifies the nuclear magnetic resonance signal received by the closed conductor loop, and a housing section in which the preamplifier section is housed and which is more rigid than the outer cover section. The RF receiving coil is mounted on the object in a state where the main body is bent such that the end surfaces of both ends of the main body face each other, and the MRI apparatus performs imaging using such an RF receiving coil.

### TECHNICAL FIELD

The present invention relates to an RF receiving coil used in a nuclear magnetic resonance imaging (hereinafter, referred to as “MRI”) apparatus that measures a nuclear magnetic resonance (hereinafter, referred to as “NMR”) signal from hydrogen, phosphorus, or the like in an object and images nuclear density distribution, relaxation time distribution, or the like.

### BACKGROUND ART

The MRI apparatus is an apparatus that measures an NMR signal generated by the object, especially, the spin of nuclei which form human tissue, and images the shapes or functions of the head, abdomen, limbs, and the like in a two-dimensional manner or in a three-dimensional manner. In the imaging, different phase encoding is given to NMR signals by the gradient magnetic field and frequency encoding is also given to the NMR signals, and the NMR signals are measured as time-series data. The measured NMR signals are reconstructed as an image by a two-dimensional or three-dimensional Fourier transform.

In the above MRI apparatus, a high-frequency receiving coil (hereinafter, referred to as an RF receiving coil) is used in order to receive NMR signals. In order to receive NMR signals with high sensitivity, it is desirable to use the RF receiving coil in a state where the RF receiving coil is adjacent to the object. For this reason, the RF receiving coil is configured in a shape allowing it to be mounted according to various body types or imaging parts of objects. For example, for the neck, an RF receiving coil disclosed in PTL 1 is known, in which the RF receiving coil is configured so as not to touch the lips or chin without disturbing the field of view of the object. Since such an RF receiving coil is divided into upper and lower sections, an antenna pattern (closed conductor loop) disposed inside is divided at a connection portion between the upper and lower sections. When the RF receiving coil is mounted on the object, the RF receiving coil is used in a state where the upper and lower sections are electrically and mechanically connected to each other at the connection portion. With this connection, an electrical closed conductor loop that surrounds the object is formed.

### CITATION LIST

### Patent Literature

[PTL 1] Japanese Patent No. 2909501

### SUMMARY OF INVENTION

### Technical Problem

In the RF receiving coil disclosed in PTL 1, in order to ensure the electrical connection of the antenna pattern divided into upper and lower sections, a locking mechanism for fixing the connection firmly is required for the connection portion. For this reason, when performing an operation of connecting the upper and lower sections to each other through the locking mechanism, a part of the object, for example, the skin or hair of the object may be pinched between the upper and lower sections near the neck. This problem has been left unsolved.

Therefore, the present invention has been made in view of the above-described problem, and it is an object of the present invention to provide an RF receiving coil having a structure that can be safely mounted on an object and an MRI apparatus including the RF receiving coil.

### Solution to Problem

An RF receiving coil of the present invention includes a main body including one or more flexible closed conductor loops for receiving an NMR signal, a flexible outer cover section that covers the closed conductor loop, a preamplifier section that amplifies the NMR signal received by the closed conductor loop, and a housing section in which the preamplifier section is housed and which is more rigid than the outer cover section. The RF receiving coil is mounted on the object in a state where the main body is bent such that the end surfaces of both ends of the main body face each other.

In addition, an MRI apparatus of the present invention includes the RF receiving coil described above.

### Advantageous Effects of Invention

In the RF receiving coil of the present invention, since the closed conductor loop is not divided, it is possible to eliminate a connection portion of the closed conductor loop. As a result, the RF receiving coil can be safely mounted on the object with no risk of pinching a part of the object.

In addition, since there is no electrical connection portion, no locking mechanism is required. Therefore, it is possible to reduce the operating burden or operating sound when mounting the RF receiving coil on the object.

In addition, since the housing section that is more rigid than the outer cover section is provided, it is possible to secure the shape and the independence of the RF receiving coil after the RF receiving coil is mounted on the object. That is, the ease of mounting based on the flexibility and the stability of the shape based on the rigidity are compatible with each other. The MRI apparatus including such an RF receiving coil can capture a high-quality image stably since the shape of the RF receiving coil is stably maintained.

### BRIEF DESCRIPTION OF DRAWINGS

FIG. 1 is a block diagram showing the overall configuration of an embodiment of an MRI apparatus related to the present invention.

FIG. 2 is a diagram showing the configuration of an RF receiving coil of a first embodiment, where FIG. 2(a) is a perspective view in a state where the RF receiving coil is deformed flat and FIG. 2(b) shows a circuit diagram of an electrical circuit unit.

FIG. 3 is a diagram showing an example when the RF receiving coil shown in FIG. 2 is mounted on the neck of the object.

FIG. 4 is a diagram showing an example in which a cut-out section is provided at the corner of the main body of the RF receiving coil shown in FIG. 2.

FIG. 5 is a diagram showing an example in which a raised section is provided at the corner of the main body of the RF receiving coil shown in FIG. 2.

FIG. 6 is a diagram, showing the configuration of an RF receiving coil of a second embodiment, where FIG. 6(a) is a perspective view in a state where the RF receiving coil is deformed flat and FIG. 6(b) shows a circuit diagram of an electrical circuit unit.

FIG. 7 is a diagram showing an example when the RF receiving coil shown in FIG. 6 is mounted on the neck of the object. FIG. 7(a) shows a perspective view in a state where the RF receiving coil shown in FIG. 6 is mounted on the object by bending the RF receiving coil so that a lid portion of a housing section faces outward, and FIG. 7(b) shows a diagram when the RF receiving coil shown in FIG. 7(a) is viewed from the head direction of the object.

FIG. 8 is a diagram showing an example in which support member is detachably fixed to the housing section. FIG. 8(a) shows a perspective view in a state where the RF receiving coil is mounted on the object, and FIG. 8(b) shows a diagram when the RF receiving coil shown in FIG. 8(a) is viewed from the head direction of the object.

FIG. 9 is a diagram showing a shape in which a recessed portion that is cut in the head direction is provided on the side surfaces of the housing section and the support member facing the shoulder so as to suit the shape of the shoulder.

FIG. 10 is a diagram showing an example in which a hinge is provided on the boundary between the housing section and the outer cover section on the face side of the object in the RF receiving coil shown in FIG. 6.

FIG. 11 is a diagram showing the configuration of an RF receiving coil of a third embodiment, where FIG. 11(a) shows a perspective view in a state where the RF receiving coil is mounted on the object, FIG. 11(b) shows a perspective view in a state where the RF receiving coil is deformed flat, and FIG. 11(c) shows a circuit diagram of an electrical circuit unit.

### DESCRIPTION OF EMBODIMENTS

Hereinafter, preferred embodiments of an MRI apparatus of the present invention will be described in detail according to the accompanying drawings. In addition, in all drawings for explaining the embodiments of the present invention, the same reference numerals are given to those with the same functions, and repeated explanation thereof will be omitted.

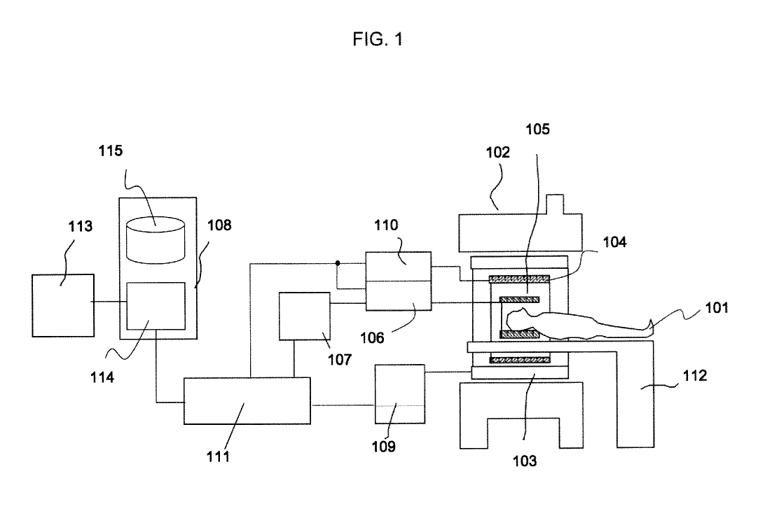

First, an MRI apparatus related to the present invention will be described on the basis of FIG. 1. FIG. 1 is a block diagram showing the overall configuration of an embodiment of the MRI apparatus related to the present invention.

This MRI apparatus acquires a tomographic image of an object 101 using an NMR phenomenon. As shown in FIG. 1, the MRI apparatus is configured to include a static magnetic field generation magnet 102, a gradient magnetic field coil 103 and a gradient magnetic field power source 109, an RF transmission coil 104 and an RF transmission unit 110, an RF receiving coil 105 and a signal detection unit 106, a signal processing unit 107, a measurement control unit 111, an overall control unit 108, a display and operation unit 113, and a bed 112 that takes a top plate, on which the object 101 is mounted, to the inside of the static magnetic field generation magnet 102 and takes out the top plate from the inside of the static magnetic field generation magnet 102.

The static magnetic field generation magnet 102 generates a uniform static magnetic field in a direction perpendicular to the body axis of the object 101 in the case of a vertical magnetic field method and in the body axis direction in the case of a horizontal magnetic field method. A permanent magnet type, a normal conducting type, or a superconducting type static magnetic field generator is disposed around the object 101.

The gradient magnetic field coil 103 is a coil wound in three axial directions of X, Y, and Z, which are the real space coordinate system (stationary coordinate system) of the MRI apparatus, and each gradient magnetic field coil is connected to the gradient magnetic field power source 109 which drives it so that a current is supplied thereto. Specifically, the gradient magnetic field power source 109 of each gradient magnetic field coil is driven according to a command from the measurement control unit 111, which will be described later, and supplies a current to each gradient magnetic field coil. As a result, the gradient magnetic fields Gx, Gy, and Gz are generated in the three axial directions of X, Y, and Z, respectively.

At the time of imaging of the two-dimensional slice surface, a slice gradient magnetic field pulse (Gs) is applied in a direction perpendicular to the slice surface (cross section of imaging) so that a slice surface of the object 101 is set, and a phase encoding gradient magnetic field pulse (Gp) and a frequency encoding (readout) gradient magnetic field pulse (Gf) are applied in the two remaining directions, which are perpendicular to the slice surface and are also perpendicular to each other, so that the positional information in each direction is encoded in an NMR signal (echo signal).

The RF transmission coil 104 is a coil which irradiates the object 101 with an RF pulse, and is connected to an RF transmission unit 110 so that a high-frequency pulse current is supplied thereto. As a result, an NMR phenomenon is induced in the spin of nuclei of atoms which form body tissue of the object 101. Specifically, the RF transmission unit 110 is driven according to a command from the measurement control unit 111, which will be described later, to perform amplitude modulation of the high-frequency pulse. By supplying this amplified pulse to the RF transmission coil 104 disposed close to the object 101, the object 101 is irradiated with the RF pulse.

The RF receiving coil 105 is a coil which receives an echo signal emitted by the NMR phenomenon of the spin of nuclei which form body tissue of the object 101, and is connected to the signal detection unit 106 so that the received echo signal is transmitted to the signal detection unit 106. The RF receiving coil related to the present invention is mounted on the neck of the object 101 in order to mainly receive an echo signal from the neck.

The signal detection unit 106 performs detection processing of the echo signal received by the RF receiving coil 105. Specifically, a response echo signal of the object 101 induced by the RF pulse irradiated from the RF transmission coil 104 is received in the RF receiving coil 105 disposed close to the object 101. The signal detection unit 106 amplifies the received echo signal according to the command from the measurement control unit 111 to be described later, divides it into two signals perpendicular to each other by quadrature phase detection, performs sampling of each signal by the predetermined number (for example, 128, 256, or 512), converts each sampling signal into the digital amount by A/D conversion, and transmits it to the signal processing unit 107 to be described later. Accordingly, the echo signal is acquired as time-series digital data (hereinafter, referred to as echo data) including a predetermined number of sampling data.

The signal processing unit 107 performs various kinds of processing on the echo data and transmits the processed echo data to the measurement control unit 111.

The measurement control unit 111 is a control unit that transmits various commands for echo data collection, which is necessary for reconstruction of a tomographic image of the object 101, mainly to the gradient magnetic field power source 109, the RF transmission unit 110, and the signal detection unit 106 in order to control them. Specifically, the measurement control unit 111 operates under the control of the overall control unit 108 to be described later, and controls the gradient magnetic field power source 109, the RF transmission unit 110, and the signal detection unit 106 on the basis of a predetermined pulse sequence to repeatedly execute the application of an RF pulse and a gradient magnetic field pulse to the object 101 and the detection of an echo signal from the object 101, and controls the collection of echo data necessary for the reconstruction of an image for an imaging region of the object 101. By these controls, the echo data from the signal processing unit 107 is output to the overall control unit 108.

The overall control unit 108 performs control of the measurement control unit 111 and control of various kinds of data processing and display, storage, and the like of the processing result, and is configured to include an arithmetic processing unit 114, which has a CPU and a memory, and a storage unit 115, such as an optical disc or a magnetic disk. Specifically, when the measurement control unit 111 is controlled to collect echo data and the echo data from the measurement control unit 111 is input, the arithmetic processing unit 114 stores the echo data in a region equivalent to the K space of the memory on the basis of the encoding information applied to the echo data. The echo data group stored in the region equivalent to the K space in the memory is also called K space data. In addition, the arithmetic processing unit 114 executes signal processing, processing for image reconstruction based on a Fourier transform, or the like on the K space data and displays an image of the object 101 which is the result on the display and operation unit 113, which will be described later, and also records the image of the object 101 in the storage unit 115.

The display and operation unit 113 includes a display unit that displays the reconstructed image of the object 101 and an operating unit used to input various kinds of control information of the MRI apparatus or control information of processing performed by the overall control unit 108, such as a track ball, a mouse, and a keyboard. This operating unit is disposed close to the display unit, so that the operator controls various kinds of processing of the MRI apparatus interactively through the operating unit while observing the display unit.

Nuclides imaged by current MRI apparatuses, which are widely used clinically, are the hydrogen nucleus (proton) which is a main constituent material of the object. The shapes or functions of the head, abdomen, limbs, and the like of the human body are imaged in a two-dimensional or three-dimensional manner by performing imaging of the spatial distribution of the proton density or the information regarding the spatial distribution of the relaxation time of the excited state.

### First Embodiment

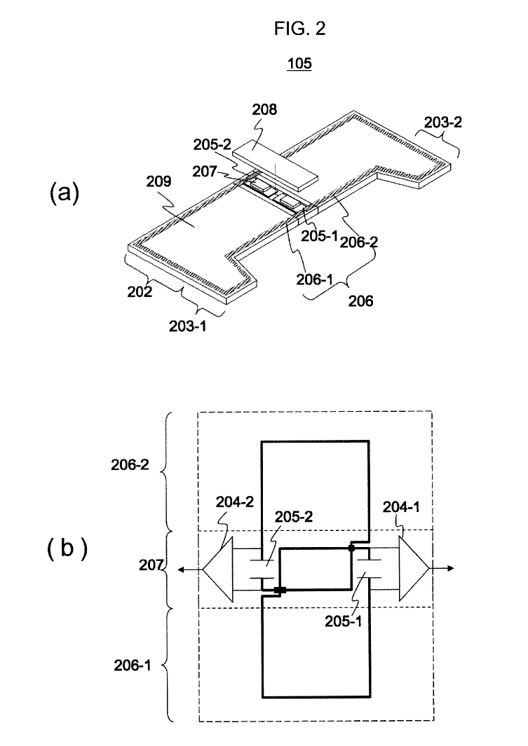

Next, a first embodiment of the RF receiving coil and the MRI apparatus of the present invention will be described. The RF receiving coil of the present embodiment has a main body including a flexible closed conductor loop for receiving an echo signal, a flexible outer cover section that covers the closed conductor loop, a preamplifier section that amplifies the echo signal received by the closed conductor loop, and a housing section in which the preamplifier section is housed and which is more rigid than the outer cover section. That is, an electrical circuit unit for receiving and amplifying an echo signal, which is formed by the closed conductor loop and the preamplifier section, is covered with the outer cover section and the housing section to form an RF receiving coil. Such an RF receiving coil is mounted on the neck of the object in a state where the RF receiving coil is bent in the shape of an approximate arc or an approximate elliptical arc so that the end surfaces of both ends of the main body of the RF receiving coil face each other. Hereinafter, the configuration of the RF receiving coil of the present embodiment will be described on the basis of FIGS. 2 to 5.

First, an example of the RF receiving coil 105 having a configuration in which a preamplifier section is disposed in an antenna pattern section, which is one closed conductor loop, will be described on the basis of FIG. 2. FIG. 2(a) slows a perspective view in a state where the RF receiving coil 105 is deformed flat, and FIG. 2(b) shows a circuit diagram of an electrical circuit unit in the RF receiving coil 105. In addition, only the circuit configuration of the electrical circuit unit is shown, and the actual shape of the antenna pattern section shown in FIG. 2(a) is not shown.

As shown in FIG. 2, the RF receiving coil of the present embodiment mainly includes a main body 202, a protruding section 203, and a housing section 208. In the RF receiving coil, an electrical circuit unit having a preamplifier section 207 and an antenna pattern section 206, which is disposed approximately symmetrically with respect to the preamplifier section 207, is provided. The housing section 208 is disposed approximately in the middle of the main body 202, and the preamplifier section 207 is housed thereinside. The antenna pattern section 206 is disposed inside the main body 202 and the protruding section 203. Protruding sections 203-1 and 203-2 are formed on the side surfaces of both ends of the main body 202, and the antenna pattern section 206 is disposed over the main body 202 and the protruding section 203. In addition, the protruding section 203 may not be provided.

The antenna pattern section 206 is formed by disposing antenna pattern sections 206-1 and 206-2, which have approximately the same shape, approximately symmetrically with respect to the housing section 208 disposed approximately in the middle of the main body 202 (more specifically, approximately axisymmetrically with respect to the transverse line perpendicular to the longitudinal center of the main body 202) such that parts of the antenna pattern sections 206-1 and 206-2 overlap each other in the housing section 208. The antenna pattern section 206-1 is a closed conductor loop in which a capacitor 205-1 is inserted, and the antenna pattern section 206-2 is a closed conductor loop in which a capacitor 205-2 is inserted. The capacitors 205-1 and 205-2 are housed in the housing section 208 together with the overlapping portions of the closed conductor loops 206-1 and 206-2. As an overlapping method of antenna pattern sections, any of the antenna pattern sections may be located above the other, but the antenna pattern sections overlap each other so as to be electrically insulated from each other. This overlapping of closed conductor loops is for canceling the coupling (so-called decoupling) of the two antenna pattern sections 606-1 and 606-2. This is the same as in embodiments described later.

The antenna pattern section 206 is formed of a flexible conductor so as to be able to be freely bent. For example, the antenna pattern section 206 may be formed of a conductive member, such as copper or aluminum formed in a thin plate shape or ribbon shape. In addition, the antenna pattern section 206 is covered with a flexible outer cover section 209, and the antenna pattern section 206 and the outer cover section 209 are integrally bent in the shape of an approximate arc or an approximate elliptical arc. In addition, although the antenna pattern section 206 is described so as to be visible from the outside in FIG. 2, the antenna pattern section 206 is not actually visible from the outside since the antenna pattern section 206 is covered with the outer cover section 209. This is the same as in other embodiments described later. In addition, the outer cover section 209 is formed of an insulating member that electrically insulates the antenna pattern section 206 from the object. For example, the outer cover section 209 may be formed of sponge-like polyurethane.

The preamplifier section 207 has an amplifier 204-1, to which signals of both ends of the capacitor 205-1 are input and which amplifies these signals, and an amplifier 204-2, to which signals of both ends of the capacitor 205-2 are input and which amplifies these signals, and is housed in the housing section 208. In addition, one amplifier is required for one closed conductor loop, and this is the same as in embodiments described later.

The housing section 208 is configured to include a base portion and a lid portion that covers the base portion, and the overlapping portion of the antenna pattern section 206 and the preamplifier section 207 are sealed and housed in the housing section 208. The housing section 208 has higher rigidity than the outer cover section 206 so that the overlapping portion of the antenna pattern section 206 and the preamplifier section 207 housed thereinside are not mechanically damaged and their shapes can be maintained without being bent. In addition, the housing section 208 is formed of an insulating member that electrically insulates the overlapping portion of the antenna pattern section 206 and the preamplifier section 207 from the object. For example, a plastic resin case may be used. By providing the highly rigid housing section 208, it is possible to stabilize the shape of the RF receiving coil 105 when the outer cover section is bent. That is, the ease of mounting of the RF receiving coil 105 based on the flexibility of the closed conductor loop and the outer cover section 209 and the stability of the shape of the RF receiving coil 105 based on the rigidity of the housing section 208 are compatible with each other.

In addition, since the RF receiving coil 105 of the present embodiment is used in a state where it is bent and mounted on the neck of the object, the RF receiving coil 105 has a shape suitable for such use. Specifically, as shown in FIG. 2, it is preferable that the RF receiving coil 105 of the present embodiment have the main body 202 and the protruding section 203. The protruding section 203 is provided as 203-1 and 203-2 on each of side surfaces of both ends of the main body 202, and is configured such that the end surface of the end of the main body 202 and the side surface of the protruding section 203 are flush with each other. Each of the protruding sections 203-1 and 203-2 covers the object from an upper portion of the neck to an upper portion of the neck-side end of the chest when the RF receiving coil 105 is bent. In addition, parts of the antenna pattern sections 206-1 and 206-2 are disposed in the protruding sections 203-1 and 203-2, respectively, so that a closed conductor loop including the protruding sections 203-1 and 203-2 is formed. In addition, the outer cover section 209 is also extended and provided so as to cover the parts of the antenna pattern section 206-1 and 206-2 disposed in the protruding sections 203-1 and 203-2. In addition, the protruding section 203 is not essential, and the RF receiving coil 105 may be formed using only the main body 202.

In addition, since the antenna loop section 206 has only a closed conductor loop structure without a cutting point or a connection point, the RF receiving coil 105 functions as an integral structure instead of a divided structure. For this reason, when mounting the RF receiving coil 105 on the object, the operator does not need to perform an operation to connect divided portions as in PTL 1. Therefore, when mounting the RF receiving coil 105 of the present embodiment on the object, there is no possibility that a part of the object will be pinched. As a result, it is possible to improve safety.

The echo signal that the electrical circuit unit having such an antenna pattern section 206 has received is output after being converted into an electrical signal. That is, the antenna pattern section 206 generates an electrical signal based on the law of electromagnetic induction by checking a change in magnetic flux passing through the inside of the closed conductor loop, that is, an echo signal, and the preamplifier section 207 detects and amplifies the electrical signal and outputs it to the signal detection unit 106.

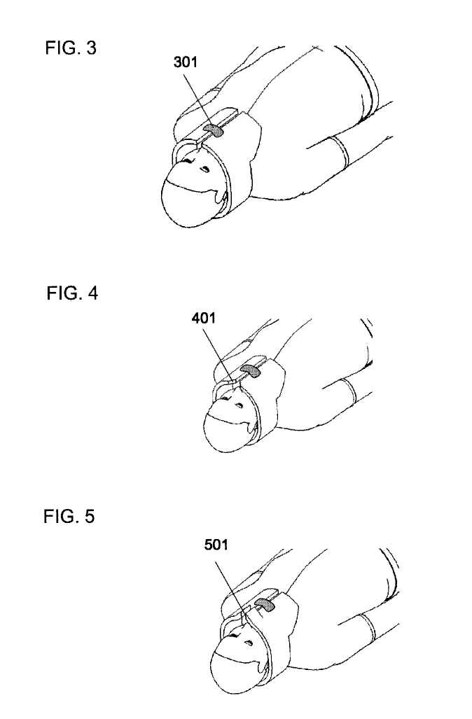

Next, an example in which the RF receiving coil of the present embodiment is mounted on the neck of the object will be described on the basis of FIG. 3. As shown in FIG. 3, with the preamplifier section 207 down in order that the ends of the outer cover section 209 that covers the antenna pattern sections 206-1 and 206-2 on both sides do not overlap at the upper position of the preamplifier section 207, the RF receiving coil 105 is mounted on the neck of the object in a state where the RF receiving coil 105 is bent so that the end surfaces of both ends face each other. That is, the outer cover section 209 and the antenna pattern sections 206-1 and 206-2 on both sides are inwardly bent approximately symmetrically in the shape of an approximate arc or an approximate elliptical arc so that both ends of the outer cover section 209 are located on the upper side (that is, the face side of the object). When the protruding section 203 is provided, the RF receiving coil 105 is bent so that the end surfaces of both ends of the main body 202 face each other and the side surfaces of both the protruding sections 203 face each other. In addition, after the RF receiving coil 105 is bent, both ends of the outer cover section 209 are fixed using a fixing member 301, such as a surface fastener. When fixing the ends, it is possible to provide a slight gap between the end surfaces of the ends of the outer cover section 209.

As a result of such bending, the preamplifier section 207 is disposed opposite the back of the head of the object, the antenna pattern sections 206-1 and 206-2 on both sides are wound around the neck of the object to cover the neck, and opposite places of the end surfaces of the ends of the antenna pattern sections 206-1 and 206-2 on both sides are located on the face of the object. In addition, the protruding section 203 extends in the body axis direction of the object from the main body 202 to cover the object up to the upper end of the chest. As a result, since the antenna pattern section 206 has sensitivity up to the upper end of the chest of the object, it is possible to capture a high-quality image including not only the neck but also the upper end of the chest.

After use, both ends of the outer cover section 209 are opened by releasing the fixing member 301, and the outer cover section 209 on both sides and the antenna pattern sections 206-1 and 206-2 are restored to the states before bending so that the RF receiving coil 105 has an approximately flat shape. Then, the RF receiving coil 105 is made away from the object.

In addition, since both ends of the main body 202 are disposed above the nose of the object when bent, a shape that can avoid contact with the nose is preferable. The example is shown in FIGS. 4 and 5. FIG. 4 shows an example in which a cut-out section 401 is provided at the corner of the main body 202, and FIG. 5 shows an example in which a raised section 501 is provided at the corner of the main body 202. In addition, the antenna pattern section 206 is also deformed corresponding to such deformation of the main body 202.

As described above, the RF receiving coil of the present embodiment includes an electrical circuit unit that includes an antenna pattern section, which is a flexible closed conductor loop, and a preamplifier section, which amplifies a signal from the antenna pattern section, the RF receiving coil can be made to have a structure without a divided structure or an electrical connection portion. As a result, the RF receiving coil can be safely mounted on the object without pinching a part of the object. In addition, an electrical connection portion can be eliminated. Therefore, since no locking mechanism is required, it is possible to reduce the operating burden or operating sounds when mounting the RF receiving coil on the object.

In addition, since the RF receiving coil of the present embodiment is configured to include a flexible antenna pattern section, a flexible outer cover section, and a housing section that is more rigid than the cuter cover section, the RF receiving coil can be easily bent. Accordingly, the RF receiving coil can be used in a state where it is wound around an imaging part of the object so as to cover the imaging part. In addition, it is possible to stably secure the shape and the independence of the RF receiving coil after the RF receiving coil is mounted on the object. That is, the ease of mounting of the RF receiving coil based on the flexibility and the stability of the shape of the RF receiving coil based on the rigidity are compatible with each other.

When the neck of the object is imaged with an MRI apparatus using such an RF receiving coil, the shape of the RF receiving coil is stably maintained. Accordingly, since it is possible to prevent the deformation of the RF receiving coil during imaging, it is possible to stably capture a high-quality image.

### Second Embodiment

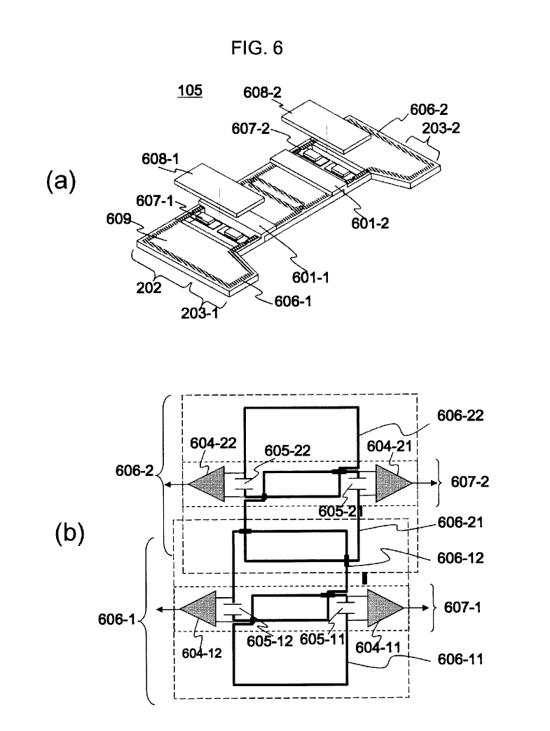

Next, a second embodiment of the RF receiving coil and the MRI apparatus of the present invention will be described. In the RF receiving coil of the present embodiment, the preamplifier section and the housing section for the housing of the preamplifier section are provided in two places of the RF receiving coil. In each housing section, a support member for supporting the RF receiving coil from the top plate on which the object is mounted is provided. Hereinafter, an example of the configuration of the RF receiving coil of the present embodiment will be described on the basis of FIGS. 6 to 10.

When the outer cover section is flexible, the RF receiving coil is flexible. Accordingly, the upper portion of the RF receiving coil mounted on the object may ride around the lips or chin of the object, and this may have an adverse effect on the comfort of the object. In order to prevent this flexion, the RF receiving coil of the present embodiment has a structure in which a housing section 608, which is more rigid than an outer cover section 609, is provided at each position of the main body near the left and right ears of the object when the RF receiving coil is mounted on the object and an overlapping portion of an antenna pattern section and a preamplifier section are housed in each housing section 608. That is, the RF receiving coil of the present embodiment is configured to have two housing sections in total by disposing the housing section 608 for housing of the preamplifier section at positions that are approximately symmetrical with respect to the middle of the main body.

First, an example of the RF receiving coil of the present embodiment will be described on the basis of FIG. 6. FIG. 6(a) is a perspective view in a state where the RF receiving coil 105 is deformed flat, and FIG. 6(b) shows a circuit diagram of the electrical circuit unit. In addition, only the circuit configuration of the electrical circuit unit is clearly shown, and the actual shape of the antenna pattern section shown in FIG. 6(a) is not shown. As shown in FIG. 6(a), antenna pattern sections 606-1 and 606-2 are not shifted in the longitudinal direction of the main body 202. In FIG. 6(b), however, the antenna pattern sections 606-1 and 606-2 are shifted in the horizontal direction intentionally in order to show the circuit diagram of the antenna pattern sections 606-1 and 606-2 better.

As shown in FIG. 6, the RF receiving coil 105 of the present embodiment is configured to have two antenna pattern sections 606 and two preamplifier sections 607 in total by disposing the antenna pattern section 606 and the preamplifier section 607 at positions that are approximately symmetrical with respect to the middle of the main body.

In addition, also in the present embodiment, a configuration is preferable in which the protruding section 203 is provided on each side surface of both ends of the main body 202, as in the RF receiving coil in the first embodiment described above. However, the protruding section 203 may not be provided. When the protruding section 203 is provided, it is preferable that the end surface of the end of the main body 202 and the side surface of the protruding section 203 be flush with each other as shown in FIG. 6.

The antenna pattern section 606 has the antenna pattern sections 606-1 and 606-2 each of which has the same electrical circuit configuration as the antenna pattern section 206 in the first embodiment described above. That is, the antenna pattern section 606-1 has antenna pattern sections 606-11 and 606-12 that are two closed conductor loops disposed such that parts of the antenna pattern sections 606-11 and 606-12 overlap each other, and the antenna pattern section 606-2 has antenna pattern sections 606-21 and 606-22 that are two closed conductor loops disposed such that parts of the antenna pattern sections 606-21 and 606-22 overlap each other. When the protruding sections 203-1 and 203-2 are provided on the side surfaces of both ends of the main body 202, the antenna pattern section 606-11 forms a closed conductor loop including the protruding section 203-1, and the antenna pattern section 606-22 forms a closed conductor loop including the protruding section 203-2.

In addition, the antenna pattern section 606-12 and the antenna pattern section 606-21 are disposed approximately in the middle of the main body 202 in such a manner that their closed conductor loops become parts of each other.

In addition, for the overlapping of the antenna pattern sections, any of the antenna pattern sections may be located above the other. As in the first embodiment, these overlapping portions are for decoupling of the closed conductor loops.

As a result of the configuration described above, the antenna pattern sections 606-1 and 606-2 are disposed approximately symmetrically with respect to the middle such that parts of the antenna pattern sections 606-1 and 606-2 overlap each other in the middle of the main body 202.

Each of the antenna pattern sections 606-11, 606-12, 606-21, and 606-22 is formed of a flexible conductor so as to be able to be freely bent. In addition, the antenna pattern section 606 is covered with the flexible outer cover section 209, and the antenna pattern section 606 and the outer cover section 609 are integrally bent.

A housing section 608-1 is disposed approximately in the middle of the antenna pattern section 606-1. The housing section 608-1 is configured to include a base portion and a lid portion that covers the base portion, and overlapping portions of the closed conductor loops of the antenna pattern sections 606-11 and 606-12 and a preamplifier section 607-1 are housed in the base portion and are covered with the lid portion to seal them. The preamplifier section 607-1 has an amplifier 604-11, to which signals of both ends of a capacitor 605-11 inserted in the closed conductor loop of the antenna pattern section 606-11 are input and which amplifies these signals, and an amplifier 604-12, to which signals of both ends of a capacitor 605-12 inserted in the closed conductor loop of the antenna pattern section 606-12 are input and which amplifies these signals.

Similarly, a housing section 608-2 is disposed approximately in the middle of the antenna pattern section 606-2. The housing section 608-2 is configured to include a base portion and a lid portion that covers the base portion, and overlapping portions of the closed conductor loops of the antenna pattern sections 606-21 and 606-22 and a preamplifier section 607-2 are housed in the base portion and are covered with the lid portion to seal them. The preamplifier section 607-2 has an amplifier 604-21, to which signals of both ends of a capacitor 605-21 inserted in the closed conductor loop of the antenna pattern section 606-21 are input and which amplifies these signals, and an amplifier 604-22, to which signals of both ends of a capacitor 605-22 inserted in the closed conductor loop of the antenna pattern section 606-22 are input and which amplifies these signals.

The housing sections 608-1 and 608-2 are more rigid than the outer cover section 609, and protect the overlapping portions of the antenna pattern sections and the preamplifier section that are housed thereinside.

In addition, each of plate-shaped support members 601-1 and 601-2 is fixed to one end of the base portion of each of the housing sections 608-1 and 608-2, which is located on the middle side of the main body 202, integrally or by mean of a screw in a stepped shape. Accordingly, a cross section of the structure in which the base portion of the housing section 608 and a support member 601 are integrally formed has a stepped structure with a two-stage stepped shape. In addition, in a state where the lid portion of the housing section 608 is mounted on the base portion, the upper surface of the lid portion and the upper surface of the support member 601 are flush with each other (on the same plane). In addition, the antenna pattern section 606 passes through the stepped structure, and the outer cover section is connected to both side surfaces of the base portion of the housing section 608. In addition, the stepped structure of the base portion of the housing section 608 and the support member 601 is disposed so as to be approximately symmetrically with respect to the middle of the main body 202.

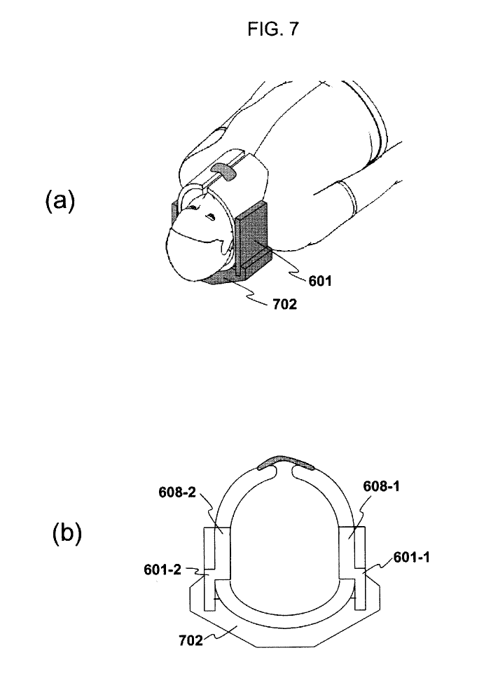

Next, an example in which the RF receiving coil of the present embodiment is mounted on the neck of the object will be described on the basis of FIG. 7. FIG. 7(a) shows a perspective view in a state where the RF receiving coil 105 shown in FIG. 6(a) is mounted on the object by bending the RF receiving coil 105 so that the lid portion of the housing section 608 faces outward, and FIG. 7(b) shows a diagram when the RF receiving coil shown in FIG. 7(a) is viewed from the head direction of the object. As described above, each of the support members 601-1 and 601-2 is provided on each base portion of the housing sections 608-1 and 608-2 of the RF receiving coil 105 so as to be integral therewith. By making the support member 601 upright so as to be perpendicular to the top plate on which the object is mounted, the support member 601 is supported from the top plate. Accordingly, the RF receiving coil 105 is supported so that the left and right sides of the RF receiving coil 105 are not independently flexible. Alternatively, as shown in FIG. 7(a), a support base 702 may be separately prepared so that the support member 701 is supported from the top plate through the support base 702 placed on the top plate. Specifically, the support base 702 has a recess, into which one end of the support member 601 can be inserted, on both the ends. One end of the support member 601 is inserted in the recess, and the support base 702 fixes the support member 601 by pinching the end. In this manner, the support base 702 supports the support member 601. Therefore, since the RF receiving coil 105 is supported by the support base 702 and the support member 601 so that the left and right sides of the RF receiving coil 105 are not flexible, the RF receiving coil 105 can maintain the shape stably. For example, the support member 601 and the support base 702 may be formed of resin, such as plastic.

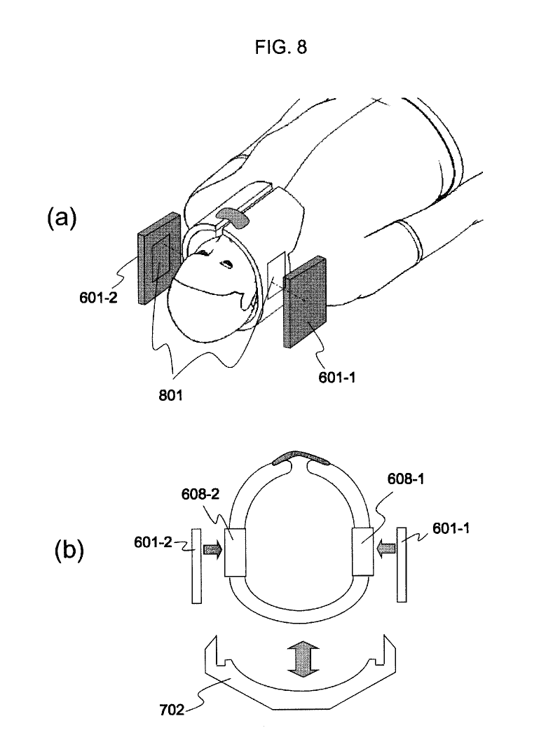

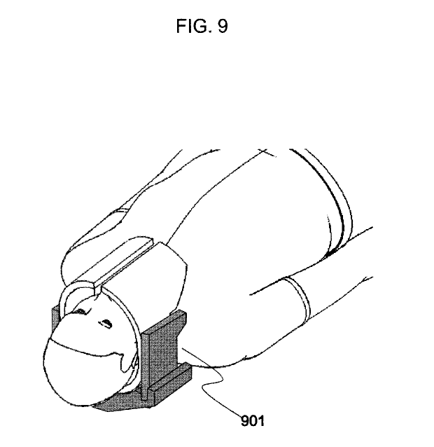

Alternatively, as shown in FIG. 8, the support member 601 may be detachably fixed to the housing section 608. FIG. 8(a) shows a perspective view in a state where the RF receiving coil 105 is mounted on the object, and FIG. 8(b) shows a diagram when the RF receiving coil shown in FIG. 8(a) is viewed from the head direction of the object. For example, a surface fastener 801 may be stuck on the upper surface of the lid portion of the housing section 608 and a surface of the support member 601 facing the upper surface of the lid portion, and the support member 601 may be detachably fixed to the housing section 608 through the surface fastener 801. After fixing the support member 601 to the housing section 608, one end of the support member 601 is inserted into the recess of the support base 702, thereby supporting the RF receiving coil from the support base 702.

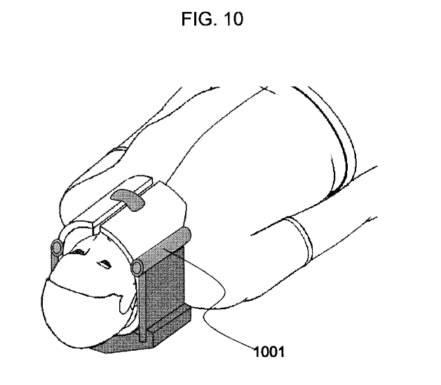

For the shapes of the housing section 601 and the support member 601, the side surface facing the shoulder of the object may touch the shoulder if the shapes are simple rectangular shapes. In order to prevent this, for example, as shown in FIG. 9, a recessed portion 901 that is cut in the head direction may be provided on the side surfaces of the housing section 608 and the support member 601 facing the shoulder so as to suit the shape of the shoulder.

In addition, although an example in which the support member 601 is detachably fixed to the support base 702 has been described in the present embodiment, it is also possible to adopt the integral structure of the support member 601 and the support base 702. In addition, it is also possible to provide an RF receiving coil including the support base 702 on the condition that the housing section 608, the support member 601, and the support base 702 are integrally formed.

In addition, by disposing a hinge 1001 on the boundary between the outer cover section 609 and the housing section 608 on the side of the face of the object as shown in FIG. 10 and connecting the outer cover section 609 and the housing section 608 to each other through the hinge 1001, it is possible to improve the durability of a connection portion between the outer cover section 609 and the housing section 608 against the bending of the outer cover section 609.

As described above, in the RF receiving coil of the present embodiment, the housing section for the housing of the preamplifier section is provided in two places of the flexible outer cover section. In each housing section, a support member for supporting the RF receiving coil from the top plate on which the object is mounted is provided. As a result, in addition to the effect of the first embodiment described above, it is possible to support the RF receiving coil by stabilizing the shape of the RF receiving coil after the RF receiving coil is mounted on the object while securing the ease of flexible mounting of the RF receiving coil on the object on the basis of the flexibility of the cuter cover section. In addition, the MRI apparatus including the RF receiving coil of the present embodiment can acquire a high-quality image stably since the shape of the RF receiving coil is not changed during imaging and accordingly the RF receiving coil is stably independent.

### Third Embodiment

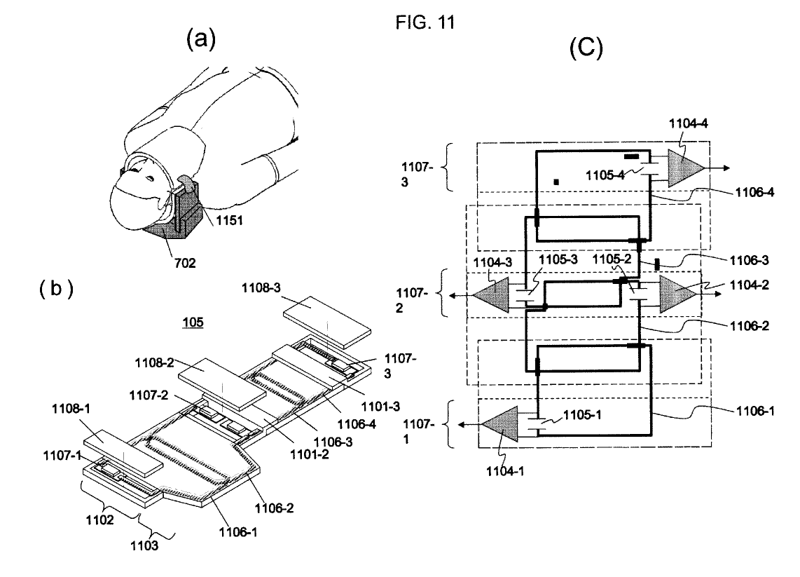

Next, a third embodiment of the RF receiving coil and the MRI apparatus of the present invention will be described. The RF receiving coil of the present embodiment is configured such that the end opposite place (hereinafter, referred to as an open end) of the RF receiving coil after bending is not the upper side of the RF receiving coil but one of the left and right sides other than the upper side. In addition, a housing section is disposed at both ends of the RF receiving coil that are open ends. Hereinafter, as an example, an example when the side surface of the RF receiving coil is an open end will be described on the basis of FIG. 11.

In the RF receiving coil of the present embodiment shown in FIG. 11, an example is shown in which the open end becomes a side surface instead of the approximate middle of the upper side of the RF receiving coil after the RF receiving coil is bent. FIG. 11(a) shows a perspective view in a state where the RF receiving coil of the present embodiment is mounted on the object, FIG. 11(b) shows a perspective view in a state where the RF receiving coil is deformed flat, and FIG. 11(c) shows a circuit diagram of an electrical circuit unit. In addition, only the circuit configuration of the electrical circuit unit is clearly shown, and the actual shape of the antenna pattern section shown in FIG. 11(b) is not shown.

The RF receiving coil of the present embodiment is similar to a configuration in which the preamplifier section 607-2 and the housing section 608-2 of the RF receiving coil in the above-described second embodiment shown in FIG. 6 are divided into two parts and the divided part located at the outer side when viewed from the main body 202 is connected to the opposite side of the main body 202 such that the antenna pattern sections 606-11 and 606-22 partially overlap each other. For this reason, the RF receiving coil of the present embodiment has three housing sections 1108-1, 1108-2, and 1108-3. In addition, the protruding sections 203-1 and 203-2 in FIG. 6 are united to form a protruding section 1103 of the RF receiving coil of the present embodiment. This is similar to the configuration where the protruding section 1103 is provided on the side surface of a main body 1102.

An antenna pattern section is configured to have four antenna pattern sections 1106-1 to 1106-4, and the antenna pattern sections 1106-1 and 1106-2, 1106-2 and 1106-3, and 1106-3 and 1106-4 are disposed so as to partially overlap each other.

A part of the antenna pattern section 1106-1 and a preamplifier section 1107-1 are sealed and housed in the housing section 1108-1. The preamplifier section 1107-1 has an amplifier 1104-1 to which signals of both ends of a capacitor 1105-1 inserted in the antenna pattern section 1106-1 are input and which amplifies these signals.

Overlapping portions of the antenna pattern sections 1106-2 and 1106-3 and a preamplifier section 1107-2 are sealed and housed in the housing section 1108-2. The preamplifier section 1107-2 has an amplifier 1104-2, to which signals of both ends of a capacitor 1105-2 inserted in the antenna pattern section 1106-2 are input and which amplifies these signals, and an amplifier 1104-3, to which signals of both ends of a capacitor 1105-3 inserted in the antenna pattern section 1106-3 are input and which amplifies these signals.

A part of the antenna pattern section 1106-4 and a preamplifier section 1107-3 are sealed and housed in the housing section 1108-3. The preamplifier section 1107-3 has an amplifier 1104-4 to which signals of both ends of a capacitor 1105-4 inserted in the antenna pattern section 1106-4 are input and which amplifies these signals.

Each of the housing sections 1108-1, 1108-2, and 1108-3 is configured to include a base portion, in which antenna pattern sections or overlapping portions thereof and a preamplifier section is housed, and a lid portion that covers the base portion, as in each embodiment described above.

In addition, as in the second embodiment described above, each of support members 1101-2 and 1101-3 is fixed to one end of the base portion of each of the housing sections 1108-1 and 1108-2 integrally or by means of a screw stop in a stepped shape, and the cross section of the structure in which the base portion of the housing section and the support member are integrally formed has a stepped structure with a two-stage stepped shape. In addition, these stepped structures are disposed so as to face each other.

The protruding section 1103 is provided on the side surface of the main body between the housing sections 1108-1 and 1108-2. The protruding section 1103 is formed to cover the object from an upper portion of the neck to a neck-side upper end of the chest when the RF receiving coil 105 of the present embodiment is mounted on the object. In addition, the antenna pattern sections 1106-1 and 1106-2 and their overlapping portions are disposed over the main body 1102 and the protruding section 1103.

Next, an example in which the RF receiving coil 105 of the present embodiment is mounted on the neck of the object will be described on the basis of Fig. (a). Fig. (a) shows a perspective view in a state where the RF receiving coil 105 shown in Fig. (b) is mounted on the object after the RF receiving coil 105 is bent such that the lid portion of each housing section faces outward. At the time of mounting, the RF receiving coil 105 is wound around the neck of the object in a state where the housing sections 1108-2 and 1108-3 are disposed near the ears of the object and support members provided in the housing sections 1108-2 and 1108-3 are positioned so as to be perpendicular to the top plate or the support base. As a result, the housing sections 1108-1 and 1108-3 face each other on the open end, the open end is located on the side surface of the object, and the protruding section 1103 covers the object up to the upper end of the chest.

As a specific procedure for mounting the RF receiving coil 105, first, the housing sections 1108-2 and 1108-3 are disposed at a distance therebetween such that the support members 1106-2 and 1106-3 are perpendicular to the top plate. Alternatively, in the case of using the support base 702, the support member 601 is supported through the support base 702 by inserting one end of each of the support members 1106-2 and 1106-3 into recesses of both ends of the support base 702 disposed on the top plate. Accordingly, the shape of the RF receiving coil 105 is stabilized so that the head of the object can be housed thereinside. Then, the head of the object is housed between the housing sections 1108-2 and 1108-3. Then, the main body 1102 and the protruding section 1103 between the housing sections 1108-2 and 1108-1 are wound around the neck of the object, and the end surface of the housing section 1108-1 and the end surface of the housing section 1108-3 are made to face each other to form an open section. Finally, the housing sections 1108-1 and 1108-3 in the open section are fixed using a surface fastener 1151. When detaching the RF receiving coil 105 from the object, the above-described procedure is performed in the reverse order.

In addition, also in the RF receiving coil 105 of the present embodiment, a support member 1101 may be detachably fixed to a housing section 1108, as in the second embodiment described above. In addition, the support member 1101 and the support base 702 may be integrally formed. In addition, it is also possible to provide an RF receiving coil including the support base 702 on the condition that the housing section 1108, the support member 1101, and the support base 702 are integrally formed.

As described above, in the RF receiving coil of the present embodiment, the open end after bending is provided, for example, on the side surface of the object, instead of the upper side of the RF receiving coil. In addition, a housing section is disposed at both ends of the RF receiving coil that are open ends. As a result, in addition to the effect of the first embodiment described above, the shape of the RF receiving coil can be stabilized since it is possible to suppress the deformation of the RF receiving coil when mounting the RF receiving coil so as to be wound around the object. In particular, since highly rigid housing sections are disposed at both ends of the RF receiving coil that are open ends, it is possible to improve the stability of the shape of the RF receiving coil. The MRI apparatus including the RF receiving coil of the present embodiment can also acquire a high-quality image stably since the RF receiving coil is not deformed during imaging and accordingly the RF receiving coil is stably independent, as in the second embodiment described above.

While each embodiment of the RF receiving coil and the MRI apparatus of the present invention has been described, the RF receiving coil and the MRI apparatus of the present invention are not limited to these embodiments. For example, although an example of the RF receiving coil wound around the neck of the object has been described in each of the above embodiments, an RF receiving coil having the same configuration may also be used for the legs or the arms as well as the neck.

### REFERENCE SIGNS LIST

101: object
102: static magnetic field generation magnet
103: gradient magnetic field coil
104: RF transmission coil
105: RF receiving coil
106: signal detection unit
107: signal processing unit
108: overall control unit
109: gradient magnetic field power source
110: RF transmission unit
111: measurement control unit
112: bed
113: display and operation unit
114: arithmetic processing unit
115: storage unit

1. An RF receiving coil that is mounted on an object in order to receive a nuclear magnetic resonance signal from the object, the RF receiving coil comprising:
a main body having a flexible closed conductor loop configured to receive the nuclear magnetic resonance signal, a flexible outer cover section that covers the closed conductor loop, a preamplifier section that amplifies the nuclear magnetic resonance signal received by the closed conductor loop, and a housing section in which the preamplifier section is housed and which is more rigid than the outer cover section,
wherein the RF receiving coil is mounted on the object in a state where the main body is bent such that end surfaces of both ends of the main body face each other.

2. The RF receiving coil according to claim 1,
wherein the housing section is disposed approximately in the middle of the main body, and
the RF receiving coil is mounted on the object in a state where the main body is bent such that opposite places of the end surfaces of both the ends of the main body are disposed above the housing section.

3. The RF receiving coil according to claim 1,
wherein the main body includes a protruding section on each side surface of both the ends,
the end surface of each end of the main body and the side surface of the protruding section are configured so as to be flush with each other,
the closed conductor loop is disposed so as to include the protruding section, and
the RF receiving coil is mounted on the object in a state where the main body is bent such that the end surfaces of both the ends of the main body face each other and the side surfaces of the protruding sections face each other.

4. The RF receiving coil according to claim 1,
wherein a place on the main body facing a nose of the object is cut.

5. The RF receiving coil according to claim 1,
wherein a place on the main body facing a nose of the object is raised.

6. The RF receiving coil according to claim 1,
wherein a fixing member that fixes the opposite arrangement of the end surfaces of both the ends of the main body after the main body is bent is provided.

7. The RF receiving coil according to claim 1,
wherein two housing sections are provided in the main body, and
the RF receiving coil is mounted on the object in a state where the main body is bent such that opposite places of the end surfaces of both the ends of the main body are disposed on an upper side and the preamplifier section is disposed on left and right sides.

8. The RF receiving coil according to claim 7,
wherein the housing section includes a support member configured to support the main body.

9. The RF receiving coil according to claim 8,
wherein the support member is detachably provided in the housing section.

10. The RF receiving coil according to claim 8,
wherein, in the support member, a portion facing a shoulder of the object is cut.

11. The RF receiving coil according to claim 8,
wherein a support base configured to fix the support member is provided.

12. The RF receiving coil according to claim 1,
wherein opposite places of the end surfaces of both the ends of the main body are configured to become any one of left and right places when the main body is bent.

13. A magnetic resonance imaging apparatus comprising:
an RF receiving coil that is mounted on an object in order to receive a nuclear magnetic resonance signal from the object,
wherein the RF receiving coil includes a main body having a flexible closed conductor loop configured to receive the nuclear magnetic resonance signal, a flexible outer cover section that covers the closed conductor loop, a preamplifier section that amplifies the nuclear magnetic resonance signal received by the closed conductor loop, and a housing section in which the preamplifier section is housed and which is more rigid than the outer cover section, and
the RF receiving coil is mounted on the object in a state where the main body is bent such that end surfaces of both ends of the main body face each other.

14. The magnetic resonance imaging apparatus according to claim 13,
wherein the housing section is disposed approximately in the middle of the main body, and
the RF receiving coil is mounted on the object in a state where the main body is bent such that opposite places of the end surfaces of both the ends of the main body are disposed above the housing section.

15. The magnetic resonance imaging apparatus according to claim 13,
wherein two housing sections are provided in the main body, and
the RF receiving coil is mounted on the object in a state where the main body is bent such that opposite places of the end surfaces of both the ends of the main body are disposed on an upper side and the preamplifier section is disposed on left and right sides.
